(19) United States
(12) Patent Application Publication
(10) Pub. No.: US 2026/0243994 A1
(43) Pub. Date: Aug. 20, 2026

(54) ADJUSTMENT MECHANISM, OPTICAL SYSTEM, EXPOSURE APPARATUS, AND ARTICLE MANUFACTURING METHOD

(71) Applicant: CANON KABUSHIKI KAISHA, Tokyo (JP)

(72) Inventor: KENICHIRO ASHIKAWA, Tochigi (JP)

(21) Appl. No.: 19/536,340

(22) Filed: Feb. 11, 2026

(30) Foreign Application Priority Data
Feb. 14, 2025 (JP) 2025-022497

(51) Int. Cl. G02B 7/182; G03F 7/00

(52) U.S. Cl. CPC G02B 7/1824; G03F 7/70825

(57) ABSTRACT

An adjustment mechanism that adjusts a position and/or a shape of an optical element, includes a deformation portion, and a driver to apply a force to the optical element via the deformation portion. The deformation portion includes a first plate having first and second parts, a second plate arranged between the first plate and the optical element, having third fourth parts, and configured to transmit a force to the optical element, a first connection portion connecting the first part and the third part, and a second connection portion connecting the second part and the fourth part, an interval between the first part and the second part is smaller than an interval between the third part and the fourth part, and the driver applies a force between the first part and the second part of the first plate.

### BACKGROUND

### Field of the Technology

The present disclosure relates to an adjustment mechanism, an optical system, an exposure apparatus, and an article manufacturing method.

### Description of the Related Art

In a manufacturing process of a semiconductor device, a display device, or the like, an exposure apparatus including an optical system for projecting the pattern of an original onto a substrate can be used. The exposure apparatus includes an adjustment mechanism configured to adjust at least one of the position and shape of an optical element incorporated in the optical system so that it can improve the aberration of the optical system by the adjustment mechanism. In Japanese Patent Laid-Open No. 2010-183097, an adjusting device with a hinge joint is provided between an optical element and an optics barrel, and the posture of the optical element is changed by applying a force to the hinge joint using a screw.

In an adjustment mechanism configured to adjust at least one of the position and shape of an optical element, stress concentration may occur in a component of a driving mechanism for driving the optical element. During long-term use, the component cannot withstand the stress and may be damaged.

### SUMMARY

The present disclosure provides a technique advantageous for improving the durability of an adjustment mechanism.

The present disclosure provides an adjustment mechanism that adjusts at least one of a position and a shape of an optical element, comprising: a deformation portion; and a driver configured to apply a force to the optical element via the deformation portion, wherein the deformation portion includes a first plate including a first part and a second part, a second plate arranged between the first plate and the optical element, including a third part and a fourth part, and configured to transmit a force to the optical element, a first connection portion configured to connect the first part and the third part, and a second connection portion configured to connect the second part and the fourth part, an interval between the first part and the second part is smaller than an interval between the third part and the fourth part, and the driver applies a force between the first part and the second part of the first plate.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view schematically showing the arrangement of an exposure apparatus according to the first embodiment;

FIGS. 2A and 2B are views schematically showing the arrangement of an adjustment mechanism according to a comparative example;

FIG. 3 is a view schematically showing the deformation state of a deformation portion in the adjustment mechanism according to the comparative example;

FIGS. 4A and 4B are views schematically showing the arrangement of an adjustment mechanism according to the first embodiment;

FIG. 5 is a view for explaining the arrangement of the adjustment mechanism according to the first embodiment;

FIG. 6 is a view schematically showing the deformation state of a deformation portion in the adjustment mechanism according to the first embodiment;

FIG. 7 is a view schematically showing the arrangement of an adjustment mechanism according to the second embodiment;

FIG. 8 is a view schematically showing the arrangement of an adjustment mechanism according to the third embodiment;

FIG. 9 is a view schematically showing the arrangement of the adjustment mechanism according to the third embodiment; and

FIG. 10 is a flowchart illustrating the driving procedure of an optical element in the first to third embodiments.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and accompanying drawings, directions will be indicated on an XYZ coordinate system. In the XYZ coordinate system, the Z-axis is parallel to a vertical direction, and the X-Y plane is parallel to a horizontal plane.

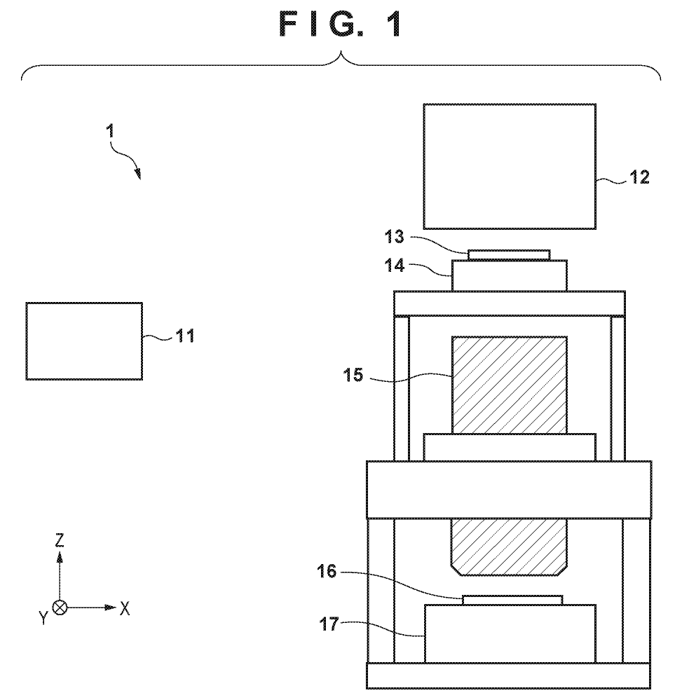

FIG. 1 schematically shows the arrangement of an exposure apparatus 1 according to an embodiment. The exposure apparatus 1 is, for example, a projection exposure apparatus that projects the pattern of an original (mask or reticle) onto a substrate 16 via a projection optical system 15 by a step-and-repeat method or a step-and-scan method, thereby exposing the substrate 16. Note that an example of the exposure apparatus will be described here, but the present disclosure is applicable to an apparatus that adjusts the aberration of an optical system by adjusting the position and shape of an optical element and is not limited to the specific embodiments described below.

The exposure apparatus 1 can include an illumination optical system 12 that emits light, the projection optical system 15 that projects the pattern of an original 13 onto the substrate 16, an original stage 14 that can move along the X-Y plane while holding the original 13, and a substrate stage 17 that can move along the X-Y plane while holding the substrate 16. The exposure apparatus 1 can also include a controller 11. For example, the original 13 includes a pattern (for example, a circuit pattern) to be transferred to the surface of silica glass, and the pattern can be formed of, for example, chrome. The substrate 16 is, for example, a single-crystal silicon substrate, and its surface is coated with a photosensitive material (resist). The controller 11 controls the respective components of the exposure apparatus 1. The controller 11 may constitute a part of an adjustment mechanism to be described later. The controller 11 can be constituted by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer with a program installed therein, or a combination of all or some of these.

In the exposure apparatus 1, exposure light from a light source (not shown) illuminates, via the illumination optical system 12, the original 13 held by the original stage 14. The light transmitted through the original 13 is applied to the substrate 16 via the projection optical system 15. The image of the light from the pattern of the original 13 is formed on the surface of the substrate 16. The exposure apparatus 1 exposes each of a plurality of shot regions on the substrate 16.

The optical characteristics of each of a plurality of optical elements incorporated in the projection optical system 15 can change due to factors such as absorption of heat generated by exposure light. This can cause the aberration of the projection optical system 15. To improve the aberration, at least one of the position and shape of at least one optical element of the projection optical system 15 can be adjusted. For example, a force is applied to the optical element in a direction (a direction along the X-Y plane) perpendicular to the optical axis (Z-axis direction) of the projection optical system 15.

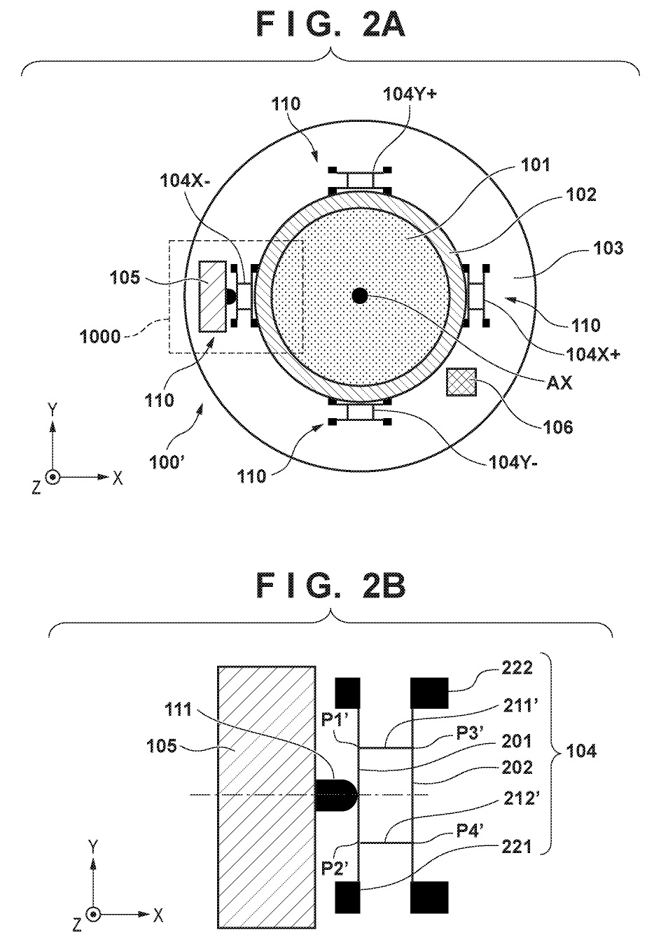

FIG. 2A shows an adjustment mechanism 100' according to a comparative example. An optical element 101 is incorporated into an optics barrel 103 of the projection optical system 15, and the optical element 101 can be held by a holder 102. The holder 102 can be fixed to the optics barrel 103 via a deformation portion 104. Alternatively, without providing the holder 102, the optical element 101 may contact the deformation portion 104 and be fixed to the optics barrel 103 via the deformation portion 104. The holder 102 can preferably be formed of a ring-shaped metal having a low thermal expansion coefficient, such as invar. The holder 102 has sufficiently high rigidity against a first plate 201 and a second plate 202 of the deformation portion 104. Four deformation portions 104 can be provided at positions in the +X-axis, -X-axis, +Y-axis, and -Y axis directions, respectively, which are almost equidistant from an optical axis AX or the center of the optical element 101. The four deformation portions 104 are indicated as 104X+, 104X-, 104Y+, and 104Y-.

In the example shown in FIG. 2A, the adjustment mechanism 100' configured to adjust at least one of the position and shape of the optical element 101 includes a plurality of deformation portions 104, and a driver 105 that applies a force to the optical element 101 via one deformation portion 104 of the plurality of deformation portions 104. However, the adjustment mechanism 100' may include two or more drivers 105 that apply a force to the optical element 101 via two or more deformation portions 104 of the plurality of deformation portions 104. Alternatively, the adjustment mechanism 100' may include a plurality of deformation portions 104, and a plurality of drivers 105 that apply a force to the optical element 101 via the plurality of deformation portions 104. The deformation portion 104 or the deformation portion 104 and the driver 105 may be understood as a support mechanism 110 for supporting the optical element 101. That is, the adjustment mechanism 100' can include a plurality of support mechanisms 110 for supporting the optical element, each of the plurality of support mechanisms 110 can include the deformation portion 104, and at least one of the pluralities of support mechanisms 110 can include the driver 105.

In the example shown in FIG. 2A, the driver 105 deforms the deformation portion 104 by applying a force to the deformation portion 104X- in the +X-axis direction, that is, by driving the deformation portion 104, under the control of the controller 11. With this, the optical element 101 connected to the deformation portion 104 moves in the +X-axis direction. Assuming repetitive operations of the driver 105, driving of the deformation portion 104 by the driver 105 can be performed within the elastic deformation range of the deformation portion 104. In an example, in a case where the deformation portion 104 is made of a metal, the deformation amount of the deformation portion 104 is 400 to 500μm at maximum, and the optical element 101 moves by almost 1/10 of the deformation amount of the deformation portion 104. The driver 105 can be, for example, a pneumatic actuator or a piezoelectric actuator, but is not limited to these.

The adjustment mechanism 100' can include a position sensor 106 configured to detect the position of the optical element 101. The position sensor 106 can detect the position of the optical element 101 and provide the result to the controller 11. The position sensor 106 can be, for example, a non-contact sensor, a capacitance sensor, or a laser interferometry sensor. Alternatively, the position sensor 106 may detect the position of the optical element 101 by using a target provided in the holder 102, or the like. The driver 105 and the position sensor 106 may be arranged inside the optics barrel 103 or may be arranged outside the optics barrel 103.

FIG. 2B is an enlarged view of a region 1000 of FIG. 2A. The deformation portion 104 can include the first plate 201 including a first part P1' and a second part P2', and the second plate 202 including a third part P3' and a fourth part P4'. The second plate 202 is arranged between the first plate 201 and the optical element 101 and transmits a force to the optical element 101. The deformation portion 104 can include a first connection portion 211' connecting the first part P1' and the third part P3', and a second connection portion 212' connecting the second part P2' and the fourth part P4'. Each of the first plate 201, the second plate 202, the first connection portion 211', and the second connection portion 212' is formed of an elastic body. The driver 105 applies a force between the first part P1' and the second part P2' (a position therebetween) of the first plate 201.

The first plate 201 and the second plate 202 are arranged parallel to each other. The first connection portion 211' and the second connection portion 212' are arranged parallel to each other. The adjustment mechanism 100' includes two first fixers 221 configured to fix the first plate 201 with respect to the optics barrel 103 serving as a member for holding the deformation portion 104, and the first part P1' and the second part P2' can be arranged between the two first fixers 221. Due to this arrangement, the first plate 201 can be deformed while the first plate 201 is fixed with respect to the optics barrel 103 by the two first fixers 221. The adjustment mechanism 100' includes two second fixers 222 configured to fix the second plate 202 with respect to the holder 102, and the third part P3' and the fourth part P4' can be arranged between the two second fixers 222. Due to this arrangement, the second plate 202 can be deformed while the second plate 202 is fixed with respect to the holder 102 by the two second fixers 222.

Each of the first fixer 221 and the second fixer 222 has sufficiently high rigidity as compared to the first plate 201, the second plate 202, the first connection portion 211', and the second connection portion 212'. The deformation portion 104 is preferably formed of a metal such as stainless steel and preferably formed as a single-piece component without welding to achieve sufficient durability. To impart elasticity to the deformation portion 104, each of the first plate 201, the second plate 202, the first connection portion 211', and the second connection portion 212' is preferably made to have a thickness of about 1/10 the thickness of each of the first fixer 221 and the second fixer 222. The first plate 201, the second plate 202, the first connection portion 211', and the second connection portion 212' preferably have the same uniform thickness.

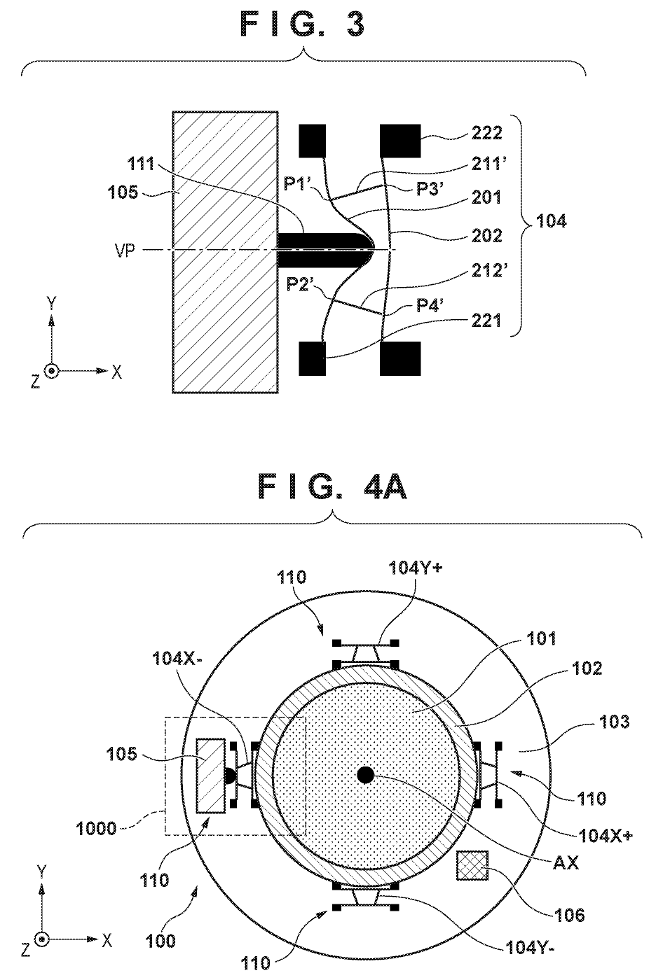

FIG. 3 schematically shows the deformation of the deformation portion 104 when a force is applied to the deformation portion 104 by the driver 105. As described above, the deformation amount of the deformation portion 104 is 400 to 500μm at maximum. In FIG. 3, the deformation amount is exaggerated. One example of simple methods for deforming the deformation portion 104 is a method of bringing a mover 111 of the driver 105 into contact with the central portion of the first plate 201 and applying a force. At this time, to improve the reproducibility of contact, one of the mover 111 and the first plate 201 at the contact point between the mover 111 and the first plate 201 is preferably formed to have a spherical shape.

In the example shown in FIG. 3, the distal end of the mover 111 of the driver 105 comes into contact with the first plate 201 and applies a force to the first plate 201 in the +X-axis direction, thereby deforming the first plate 201. In the comparative example, the interval between the first part P1' and the second part P2' is equal to the interval between the third part P3' and the fourth part P4'. Accordingly, the rigidity of a portion between the first part P1' and the second part P2' of the first plate 201 is almost equal to the rigidity of a portion between the third part P3' and the fourth part P4' of the second plate 202. Therefore, the first plate 201, to which a force is applied when the distal end of the mover 111 comes into contact with the first plate 201, can deform extremely significantly as compared to the second plate 202. Hence, stress concentration occurs in each of the first part P1' and the second part P2' of the first plate 201, and it is difficult to achieve high durability (for example, being maintenance-free for 10 to 20 years). Furthermore, since the deformation amount of the second plate 202 in the +X-axis direction is smaller than that of the first plate 201, a problem that the driving amount of the optical element 101 is small also occurs.

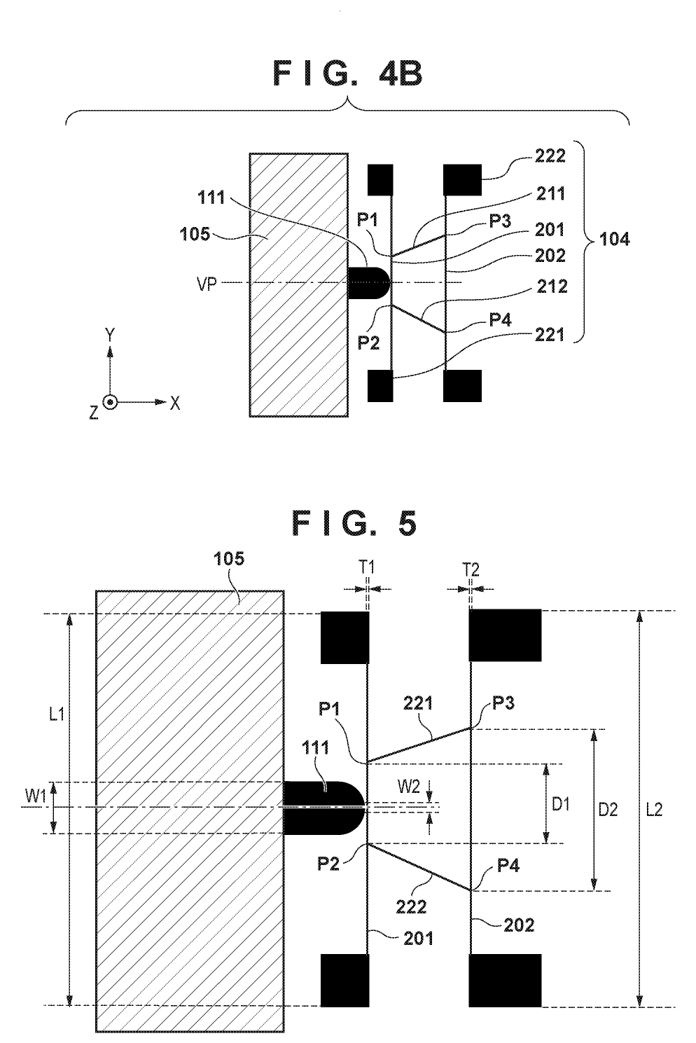

An adjustment mechanism 100 and an exposure apparatus 1 according to the first embodiment will be described below. Matters not mentioned in the description of the first embodiment can follow the above description. FIG. 4A shows the adjustment mechanism 100 according to the first embodiment. The adjustment mechanism 100 according to the first embodiment is different from the comparative example in the arrangement of a deformation portion 104, and similar to the comparative example in the remaining points. The adjustment mechanism 100 may include a holder 102 that holds an optical element 101. In a case where the adjustment mechanism 100 includes the holder 102, a driver 105 can adjust at least one of the position and shape of the optical element 101 via the holder 102 by applying a force to the side surface of the holder 102. In a case where the adjustment mechanism 100 does not include the holder 102, the optical element 101 can contact the deformation portion 104 and be fixed to an optics barrel 103 via the deformation portion 104.

FIG. 4B is an enlarged view of a region 1000 of FIG. 4A. FIG. 5 is an enlarged view of FIG. 4B. The deformation portion 104 can include a first plate 201 including a first part P1 and a second part P2, and a second plate 202 including a third part P3 and a fourth part P4. The second plate 202 is arranged between the first plate 201 and the optical element 101 and transmits a force to the optical element 101. The deformation portion 104 can include a first connection portion 211 connecting the first part P1 and the third part P3, and a second connection portion 212 connecting the second part P2 and the fourth part P4. Each of the first plate 201, the second plate 202, the first connection portion 211, and the second connection portion 212 is formed of an elastic body. The driver 105 applies a force between the first part P1 and the second part P2 (a position therebetween) of the first plate 201.

The first plate 201 and the second plate 202 are arranged parallel to each other. In the first embodiment, an interval D1 between the first part P1 and the second part P2 is smaller than an interval D2 between the third part P3 and the fourth part P4. The interval D1 between the first part P1 and the second part P2 can be, for example, 0.8 times or less, 0.7 times or less, or 0.6 times or less of the interval D2 between the third part P3 and the fourth part P4. The interval D1 between the first part P1 and the second part P2 can be, for example, 0.2 times or more, 0.3 times or more, or 0.4 times or more of the interval D2 between the third part P3 and the fourth part P4.

The adjustment mechanism 100 includes two first fixers 221 configured to fix the first plate 201 with respect to the optics barrel 103 serving as a member for holding the deformation portion 104, and the first part P1 and the second part P2 can be arranged between the two first fixers 221. Due to this arrangement, the first plate 201 can be deformed while the first plate 201 is fixed with respect to the optics barrel 103 by the two first fixers 221. The adjustment mechanism 100 includes two second fixers 222 configured to fix the second plate 202 with respect to the holder 102, and the third part P3 and the fourth part P4 can be arranged between the two second fixers 222. Due to this arrangement, the second plate 202 can be deformed while the second plate 202 is fixed with respect to the holder 102 by the two second fixers 222. Each of the first fixer 221 and the second fixer 222 has sufficiently high rigidity as compared to the first plate 201, the second plate 202, the first connection portion 211, and the second connection portion 212. The deformation portion 104 is preferably formed of a metal such as stainless steel and preferably formed as a single-piece component without welding to achieve sufficient durability. To impart elasticity to the deformation portion 104, each of the first plate 201, the second plate 202, the first connection portion 211, and the second connection portion 212 is preferably made to have a thickness of about 1/10 the thickness of each of the first fixer 221 and the second fixer 222.

The first plate 201, the second plate 202, the first connection portion 211, and the second connection portion 212 can be arranged symmetrically with respect to a virtual plane VP including the position where a force is applied to the first plate 201 by the driver 105 and an optical axis AX of the optical element 101. With this arrangement, a force can be applied to the optical element 101 with high reproducibility.

A thickness T2 of the second plate 202 can be 0.9 times or more and 1.1 times or less, 0.95 times or more and 1.05 times or less, or 0.97 times or more and 1.03 times or less of a thickness T1 of the first plate 201. In a direction (the depth direction of FIG. 5) parallel to the optical axis AX of the optical element 101, the dimension of the second plate 202 can be 0.9 times or more and 1.1 times or less, 0.95 times or more and 1.05 times or less, or 0.97 times or more and 1.03 times or less of the dimension of the first plate 201. In a direction orthogonal to the virtual plane VP including the optical axis AX of the optical element 101 and the position where a force is applied to the first plate 201 by the driver 105, a dimension L2 of the second plate 202 can be 0.9 times or more and 1.1 times or less of a dimension L1 of the first plate 201. Alternatively, the dimension L2 of the second plate 202 can be 0.95 times or more and 1.05 times or less, or 0.97 times or more and 1.03 times or less of the dimension L1 of the first plate 201.

The driver 105 includes a mover 111 used to apply a force to the first plate 201. In a direction orthogonal to a direction from the mover 111 toward the optical axis AX of the optical element 101, a width W1 of the mover 111 may be smaller than the interval D1 between the first part P1 and the second part P2. From another viewpoint, the mover 111 includes a distal end portion that comes into contact with the first plate 201. In a direction orthogonal to a direction from the mover 111 toward the optical axis AX of the optical element 101, a width W2 of the distal end portion may be smaller than the interval D1 between the first part P1 and the second part P2.

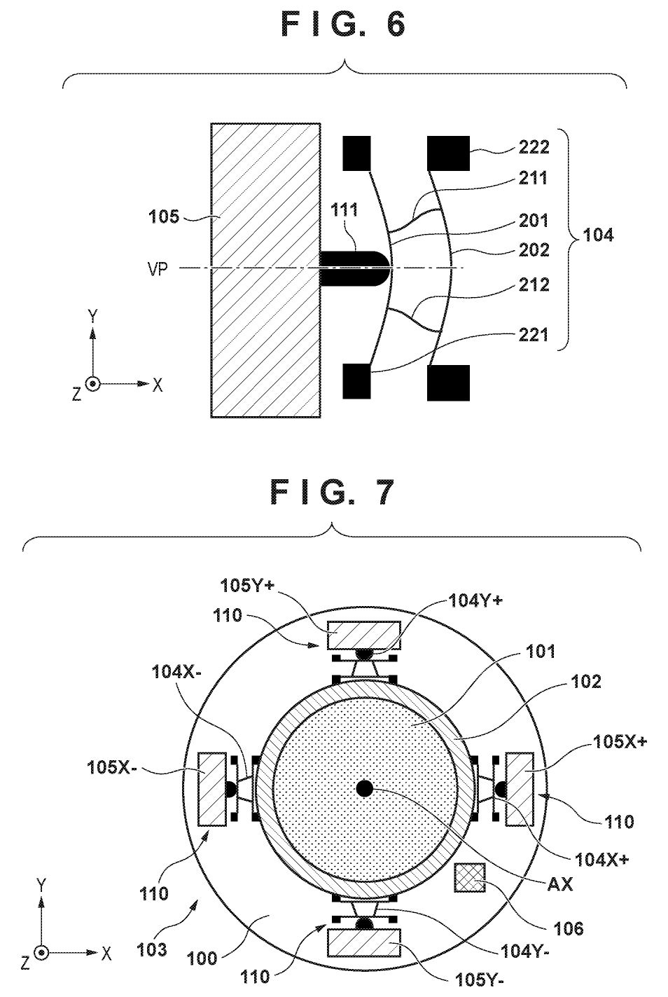

In the example shown in FIG. 6, the distal end of the mover 111 of the driver 105 comes into contact with a portion of the first plate 201 between the first part P1 and the second part P2, and the distal end of the mover 111 applies a force to the first plate 201 in the +X-axis direction, thereby deforming the first plate 201. In the first embodiment, the interval D1 between the first part P1 and the second part P2 is smaller than the interval D2 between the third part P3 and the fourth part P4. Accordingly, the rigidity of the portion of the first plate 201 between the first part P1 and the second part P2 is higher than the rigidity of the portion of the second plate 202 between the third part P3 and the fourth part P4. Therefore, the difference between the deformation amount of the first plate 201 and the deformation amount of the second plate 202 when a force is applied to the first plate 201 by the distal end of the mover 111 is smaller in the first embodiment than in the comparative example. Hence, according to the first embodiment, as compared to the comparative example, the durability of the deformation portion 104, and the durability of the adjustment mechanism 100 improve. Furthermore, according to the first embodiment, it is possible to drive the optical element 101 more efficiently than in the comparative example.

FIG. 7 shows an adjustment mechanism 100 according to the second embodiment. The adjustment mechanism 100 according to the second embodiment is different from the first embodiment in that all support mechanisms 110 respectively include drivers 105. More specifically, in the second embodiment, drivers 105X+, 105X-, 105Y+, and 105Y- are provided with respect to deformation portions 104X+, 104X-, 104Y+, and 104Y-, respectively.

X-axis driving will be taken as an example and described below. This description is also applicable to Y-axis driving. Each driver 105 applies a force to an optical element 101 while deforming the corresponding deformation portion 104 by coming into contact with the first plate 201 of the deformation portion 104 and applying a force thereto. The driver 105X+ applies a force to the optical element 101 in the -X-axis direction, and the driver 105X- applies a force to the optical element 101 in the +X-axis direction. Therefore, when the optical element 101 is at the initial position, a predetermined force is applied to the deformation portion 104 in advance using the drivers 105X+ and 105X-. Then, when moving the optical element 101 in the +X-axis direction, the force generated by the driver 105X+ is decreased and the force generated by the driver 105X- is increased at the same time. To the contrary, when moving the optical element 101 in the -X-axis direction, the force generated by the driver 105X+ is increased and the force generated by the driver 105X- is decreased at the same time. Thus, the optical element 101 can be moved in both directions regarding the X-axis.

For example, letting F be the force required to move the optical element 101 by the maximum amount by one driver 105, the force applied to the optical element 101 at the initial position may be 1/2F + ΔF. ΔF is a force which is additionally applied during driving to ensure the contact between the driver 105 and the deformation portion 104. ΔF is a force required to prevent the spring constant of the system from changing during driving. On the other hand, when moving the optical element 101 without deforming it, it should be avoided to set ΔF larger than necessary, and it is preferable to set ΔF to about 1/5F. For example, when moving the optical element 101 in the +X-axis direction by the maximum amount, the driver 105X+ generates a force of ΔF, and the driver 105X- generates a force of F + ΔF.

In the arrangement shown in FIG. 6, when moving the optical element 101 in an arbitrary axis direction, the friction between the deformation portion 104 and a mover 111 of the driver 105 on the opposite side of the driving axis may cause hysteresis during driving, and this can lower the driving accuracy. Forming the distal end of the mover 111 from a low friction material or coating the distal end of the mover 111 with a lubricant is expected to improve the driving accuracy.

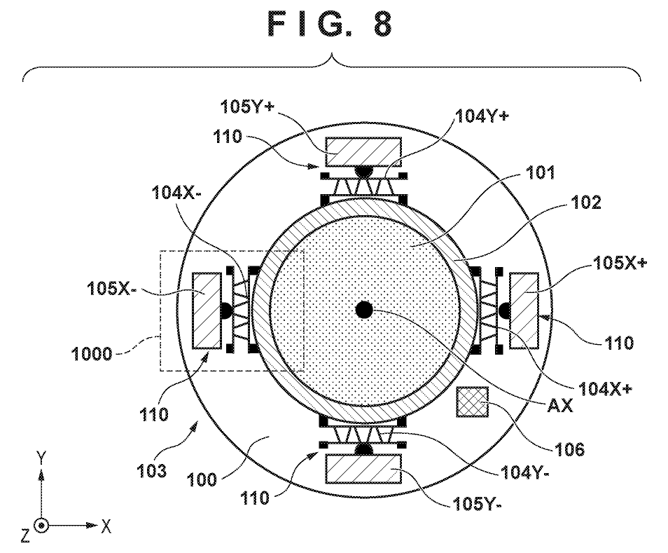

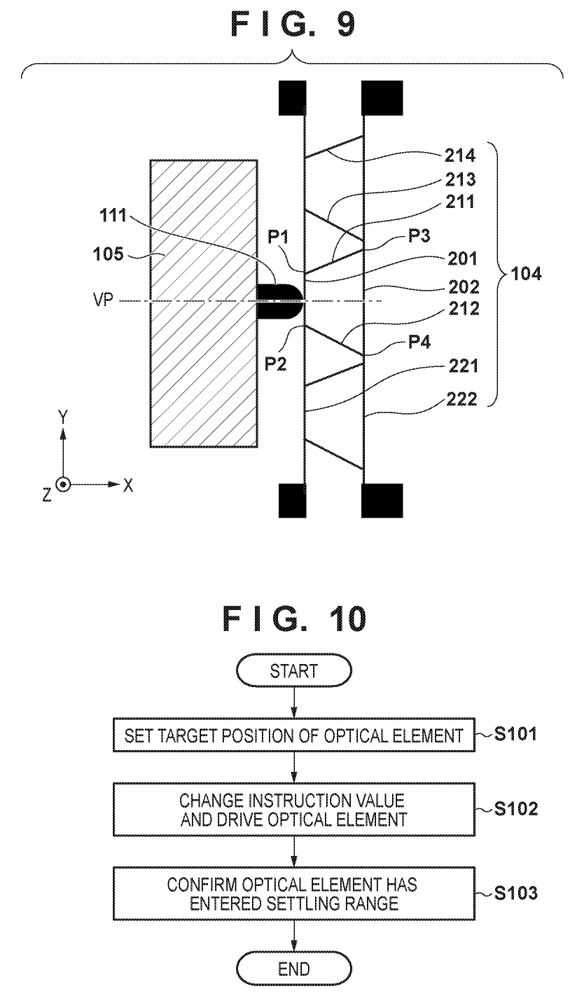

FIG. 8 shows an adjustment mechanism 100 according to the third embodiment. FIG. 9 is an enlarged view of a region 1000 of FIG. 8. Matters not mentioned in the description of the third embodiment can follow the first or second embodiment. In the third embodiment, one or a plurality of connection portion pairs, which are similar to a connection portion pair made of a first connection portion 211 and a second connection portion 212, are additionally provided. In the example shown in FIG. 8, three connection portion pairs are arranged between a first plate 201 and a second plate 202 in one deformation portion 104.

Each added connection portion pair includes a third connection portion 213 and a fourth connection portion 214. Here, the interval between a part where the first plate 201 and the third connection portion 213 are connected and a part where the first plate 201 and the fourth connection portion 214 are connected is an interval D3. The interval between a part where the second plate 202 and the third connection portion 213 are connected and a part where the second plate 202 and the fourth connection portion 214 are connected is an interval D4. In each added connection portion pair, D3 is preferably smaller than D4.

FIG. 10 illustrates the driving procedure of the optical element 101 in the first to third embodiments. In step S101, the controller 11 sets the target position of the optical element 101. Here, data indicating the relationship between an exposure recipe and the aberration change of the projection optical system may be acquired in advance, and the driving amount of the optical element 101 may be set in advance for each exposure recipe. Alternatively, the aberration change may be continuously monitored, and the target position may be set when the aberration change reaches a threshold. Alternatively, the target position may be set using another method.

Next, in step S102, the controller 11 changes an instruction value to be supplied to the driver 105, and causes the driver 105 to drive the optical element 101 in accordance with the instruction value. Here, control (open control) can be employed in which data indicating the relationship between the instruction value supplied to the driver 105 and the moving amount of the optical element 101 is acquired in advance, and the instruction value is changed based on the data. Alternatively, control (feedback control) may be employed in which the position sensor 106 detects the moving amount or position of the optical element 101, and the instruction value to be supplied to the driver 105 is adjusted based on the output of the position sensor 106.

In step S103, the controller 11 confirms, using the position sensor 106, that the position of the optical element 101 has entered within the settling range relative to the target position. Note that step S103 may be omitted if the driving accuracy and static stability of the optical element 101 permits. If open control is employed as the control in step S102, the position sensor 106 is unnecessary.

The first to third embodiments may be applied to, for example, an Alvarez lens which is a pair of lenses made of two optical elements with a space between the two optical elements. When the Alvarez lens includes the first optical element and the second optical element, it is possible to drive the optical element 101 by the adjustment mechanism 100 for at least one of the first optical element and the second optical element. This can change the aberration caused by the relative displacement between the first optical element and the second optical element.

An article manufacturing method for manufacturing an article using the above-described exposure apparatus will be described below. The article manufacturing method can include an exposure step of exposing a substrate by the above-described exposure apparatus, and a processing step of obtaining an article by processing the substrate having undergone the exposure step. The processing step can include, for example, a developing step, and can additionally include an etching step, a sealing step, a dicing step, or the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-022497, filed February 14, 2025, which is hereby incorporated by reference herein in its entirety.

What is claimed is:

1. An adjustment mechanism that adjusts at least one of a position and a shape of an optical element, comprising:
a deformation portion; and
a driver configured to apply a force to the optical element via the deformation portion,
wherein the deformation portion includes
a first plate including a first part and a second part,
a second plate arranged between the first plate and the optical element, including a third part and a fourth part, and configured to transmit a force to the optical element,
a first connection portion configured to connect the first part and the third part, and
a second connection portion configured to connect the second part and the fourth part,
an interval between the first part and the second part is smaller than an interval between the third part and the fourth part, and
the driver applies a force between the first part and the second part of the first plate.

2. The mechanism according to claim 1, further comprising a holder configured to hold the optical element,
wherein the driver applies a force to a side surface of the holder, thereby adjusting at least one of a position and a shape of the optical element via the holder.

3. The mechanism according to claim 2, further including
two first fixers configured to fix the first plate with respect to a member holding the deformation portion
wherein the first part and the second part are arranged between the two first fixers.

4. The mechanism according to claim 3, further including
two second fixers configured to fix the second plate with respect to the holder
wherein the third part and the fourth part are arranged between the two second fixers.

5. The mechanism according to claim 1, wherein
the deformation portion further includes one or a plurality of connection portion pairs connecting the first plate and the second plate, and each connection portion pair includes a third connection portion and a fourth connection portion, and
an interval between a part where the first plate and the third connection portion are connected and a part where the first plate and the fourth connection portion are connected is smaller than an interval between a part where the second plate and the third connection portion are connected and a part where the second plate and the fourth connection portion are connected.

6. The mechanism according to claim 1, wherein
the first plate, the second plate, the first connection portion, and the second connection portion are arranged symmetrically with respect to a virtual plane including a position where a force is applied to the first plate by the driver and an optical axis of the optical element.

7. The mechanism according to claim 1, wherein
a thickness of the second plate is not less than 0.9 times and not more than 1.1 times a thickness of the first plate.

8. The mechanism according to claim 1, wherein
in a direction parallel to an optical axis of the optical element, a dimension of the second plate is not less than 0.9 times and not more than 1.1 times a dimension of the first plate.

9. The mechanism according to claim 1, wherein
in a direction orthogonal to a virtual plane including a position where a force is applied to the first plate by the driver and an optical axis of the optical element, a dimension of the second plate is not less than 0.9 times and not more than 1.1 times a dimension of the first plate.

10. The mechanism according to claim 1, wherein
the interval between the first part and the second part is not more than 0.8 times the interval between the third part and the fourth part.

11. The mechanism according to claim 10, wherein
the interval between the first part and the second part is not less than 0.2 times the interval between the third part and the fourth part.

12. The mechanism according to claim 1, wherein
the driver includes a mover configured to apply a force to the first plate and, in a direction orthogonal to a direction from the mover to an optical axis of the optical element, a width of the mover is smaller than the interval between the first part and the second part.

13. The mechanism according to claim 1, wherein
the driver includes a mover configured to apply a force to the first plate, and the mover includes a distal end portion that comes into contact with the first plate, and
in a direction orthogonal to a direction from the mover to an optical axis of the optical element, a width of the distal end portion is smaller than the interval between the first part and the second part.

14. The mechanism according to claim 1, wherein
the driver is one of a pneumatic actuator and a piezoelectric actuator.

15. The mechanism according to claim 1, further comprising a sensor configured to detect a position of the optical element,
wherein the driver is controlled based on an output of the sensor.

16. The mechanism according to claim 1, wherein
the optical element is one of lenses constituting an Alvarez lens.

17. The mechanism according to claim 1, wherein
a plurality of support mechanisms configured to support the optical element are provided, each of the plurality of support mechanisms includes the deformation portion, and at least one of the plurality of support mechanisms includes the driver.

18. An optical system comprising:
an optical element; and
an adjustment mechanism defined in claim 1, and configured to adjust at least one of a position and a shape of the optical element.

19. An exposure apparatus that exposes a substrate, comprising
an optical system defined in claim 18, and configured to project a pattern of an original onto the substrate.

20. An article manufacturing method comprising:
exposing a substrate by an exposure apparatus defined in claim 19; and
obtaining an article by processing the substrate having undergone the exposing.
